(19) United States
(12) Patent Application Publication
(10) Pub. No.: US 2011/0140156 A1
(43) Pub. Date: Jun. 16, 2011

(54) ORGANIC LIGHT EMITTING DIODE DISPLAY

(75) Inventors: Hee-Seong JEONG, Yongin-city (KR); Sung-Soo KOH, Yongin-city (KR); Tae-Gon KIM, Yongin-city (KR); Seung-Yeon CHO, Yongin-city (KR); Chul-Woo JEONG, Yongin-city (KR); Jae-Yong KIM, Yongin-city (KR)

(73) Assignee: SAMSUNG MOBILE DISPLAY CO., LTD., Yongin-city (KR)

(21) Appl. No.: 12/966,853

(22) Filed: Dec. 13, 2010

(30) Foreign Application Priority Data
Dec. 14, 2009 (KR) 10-2009-0124094

(51) Int. Cl. H01L 51/52

(52) U.S. Cl. 257/98; 257/E51.018

(57) ABSTRACT

An organic light emitting diode display is disclosed. The display includes a first electrode, an organic emissive layer placed on the first electrode, and a second electrode having a first layer placed on the organic emissive layer and a second layer disposed between the first layer and the organic emissive layer. The second layer is higher in transmittance than the first layer.

### CROSS-REFERENCE TO RELATED APPLICATIONS

This application claims priority to and the benefit of Korean Patent Application No. 10-2009-0124094 filed in the Korean Intellectual Property Office on Dec. 14, 2009, the entire contents of which are incorporated herein by reference.

### BACKGROUND

1. Field

The described technology relates generally to an organic light emitting diode display, and more particularly, to an organic light emitting diode display having a multi-layered electrode.

2. Description of the Related Technology

Organic light emitting diode displays have a self emissive characteristic, and have a relatively small thickness and weight. Organic light emitting diode displays generally exhibit high quality characteristics such as low power consumption, high luminance, and short response time.

Organic light emitting diode displays generally include a first substrate with organic light emitting diodes, and a second substrate facing the first substrate to protect the organic light emitting diodes of the first substrate.

The organic light emitting diode generally includes an organic emission layer, and first and second electrodes facing each other with the organic emission layer interposed therebetween.

One of the first and second electrodes of the organic light emitting diode in the organic light emitting diode display is generally used as a reflective electrode, and the other electrode is generally used as a transparent electrode.

When the second electrode of the organic light emitting diode is a reflective electrode functioning as a cathode, the second electrode is generally formed either with a first metallic material having high reflectivity or with a second metallic material having a low work function.

When the second electrode is formed with the first metallic material having high reflectivity, the first metallic material might be higher in work function than the second low work function metallic material.

When the second electrode is formed with the second metallic material having a low work function, the second metallic material might be lower in reflectivity than the first high reflective metallic material.

The above information disclosed in this Background section is only for enhancement of understanding of the background of the described technology and therefore it may contain information that does not form the prior art that is already known in this country to a person of ordinary skill in the art.

### SUMMARY OF CERTAIN INVENTIVE ASPECTS

One aspect is an organic light emitting diode display including: a first electrode, an organic emissive layer placed over the first electrode and configured to emit light, and a second electrode including a first layer placed over the organic emissive layer and a second layer disposed between the first layer and the organic emissive layer, where the first layer has a first transmittance and the second layer has a second transmittance, and where the second transmittance is higher than the first transmittance.

Another aspect is an organic light emitting diode display where the first layer is includes a reflective layer, and the second layer includes a semitransparent layer.

Another aspect is an organic light emitting diode display where the transmittance of the second layer is more than about 10%.

Another aspect is an organic light emitting diode display where the transmittance of the first layer is less than about 1%.

Another aspect is an organic light emitting diode display where the second layer is thinner than the first layer.

Another aspect is an organic light emitting diode display where the first layer is higher in reflectivity than the second layer.

Another aspect is an organic light emitting diode display where the first electrode functions as an anode, and the second electrode functions as a cathode.

Another aspect is an organic light emitting diode display where the second layer is lower in work function than the first layer.

Another aspect is an organic light emitting diode display where the first layer includes aluminum (Al), and the second layer includes magnesium silver (MgAg).

Another aspect is an organic light emitting diode display where the second electrode is configured such that light emitted from the organic emissive layer is partly reflected at the second layer and partly transmitted to the first layer and that the light transmitted to the first layer is mostly reflected back toward the organic emissive layer.

Another aspect is an organic light emitting device including: a first electrode, a second electrode including a semi-transmissive layer and a reflective layer, and an organic emissive layer between the first and second electrodes, where the semi-transmissive layer is positioned between the organic emissive layer and the reflective layer such that light emitted from the organic emissive layer is partially transmitted to the reflective layer and substantially reflected at the reflected layer back toward the organic emissive layer.

Another aspect is an organic light emitting device where the semi-transmissive layer includes an electrically conductive material and is in a thickness sufficient to transmit at least 10% of light incident thereto.

Another aspect is an organic light emitting device where the semi-transmissive layer is substantially thinner than the reflective layer.

Another aspect is an organic light emitting device where the material of the semi-transmissive layer would be substantially reflective in a thickness of the reflective layer.

Another aspect is an organic light emitting device where the semi-transmissive layer has a thickness from about 30 Å to about 5000 Å.

Another aspect is an organic light emitting device where the semi-transmissive layer includes an electrically conductive material having a work function substantially smaller than that of the reflective layer.

Another aspect is an organic light emitting device where the reflective layer includes an electrically conductive material and is in a thickness sufficient to reflect at least 95% of light incident thereto.

Another aspect is an organic light emitting device where the semi-transmissive layer includes MgAg.

Another aspect is an organic light emitting device where the semi-transmissive layer includes Al.

### BRIEF DESCRIPTION OF THE DRAWINGS

FIG. 1 is a cross-sectional view of an organic light emitting diode display according to an exemplary embodiment.

FIG. 2 is a layout view of a pixel structure of an organic light emitting diode display according to an exemplary embodiment.

FIG. 3 is a cross-sectional view of the organic light emitting diode display taken along the line of FIG. 2.

FIG. 4 is a magnified view of portion A of FIG. 3.

FIG. 5(a), (b), and (c) are schematic sectional views of elements in organic light emitting diode displays according to comparative examples and an exemplary embodiment, respectively.

FIG. 6(a), (b), and (c) are graphs representing the CIE color system-based light emission efficiency of the red light measured in the organic light emitting diode displays of FIG. 5.

FIG. 7(a), (b), and (c) are graphs representing the CIE color system-based light emission efficiency of the green light measured in the organic light emitting diode displays of FIG. 5.

FIG. 8(a), (b), and (c) are graphs representing the CIE color system-based light emission efficiency of the blue light measured in the organic light emitting diode displays of FIG. 5.

### DETAILED DESCRIPTION OF CERTAIN INVENTIVE EMBODIMENTS

Certain exemplary embodiments will be described more fully hereinafter with reference to the accompanying drawings. As those skilled in the art would realize, the described embodiments may be modified in various ways, without departing from the spirit or scope of the present invention.

When an element such as a layer, film, region, or substrate is referred to as being “on” another element, the element can be directly on the other element or intervening elements may also be present.

Throughout the specification, when an element is said to include another constituent element, it may additionally include other constituent elements but may not exclude them unless a specific limitation to the contrary is made. Furthermore, it will be understood throughout the specification that when an element is referred to as being “on” another element, it may be placed over or below the other element but not necessarily placed over the other element, based on the direction of gravity.

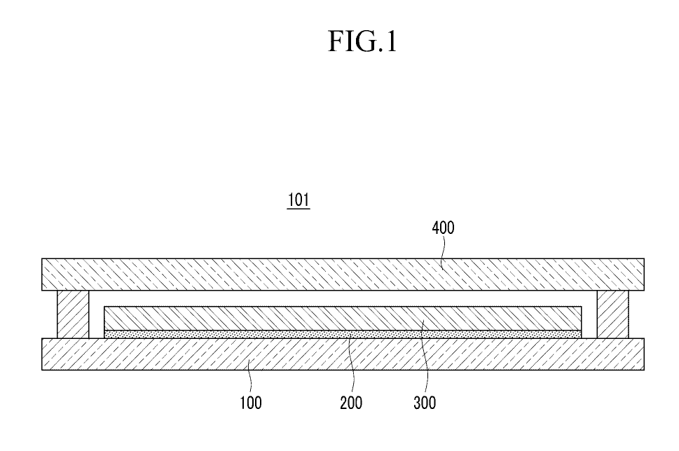

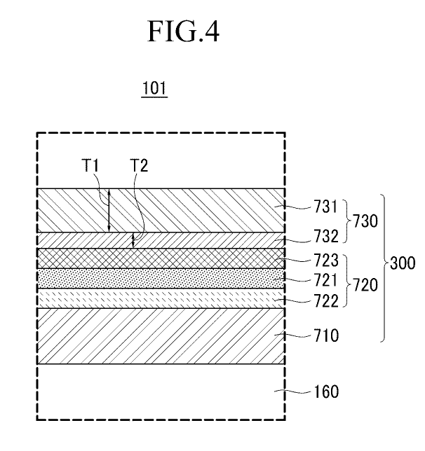

An organic light emitting diode display 101 according to an exemplary embodiment will now be described with reference to FIG. 1 thru FIG. 4.

FIG. 1 is a cross-sectional view of an organic light emitting diode display according to an exemplary embodiment.

As shown in FIG. 1, the organic light emitting diode display 101 according to an exemplary embodiment includes a first substrate 100, driving circuitry 200, an organic light emitting diode (OLED) 300, and a second substrate 400.

The first substrate 100 and the second substrate 400 are formed with light transmissive insulating material containing glass, polymer, or the like. The first substrate 100 and the second substrate 400 face each other, and are bonded together by a sealant. Driving circuitry 200 and the organic light emitting diode 300 are positioned between the first substrate 100 and the second substrate 400, and the first substrate 100 and the second substrate 400 protect the driving circuitry 200 and the organic light emitting diode 300 from external interference.

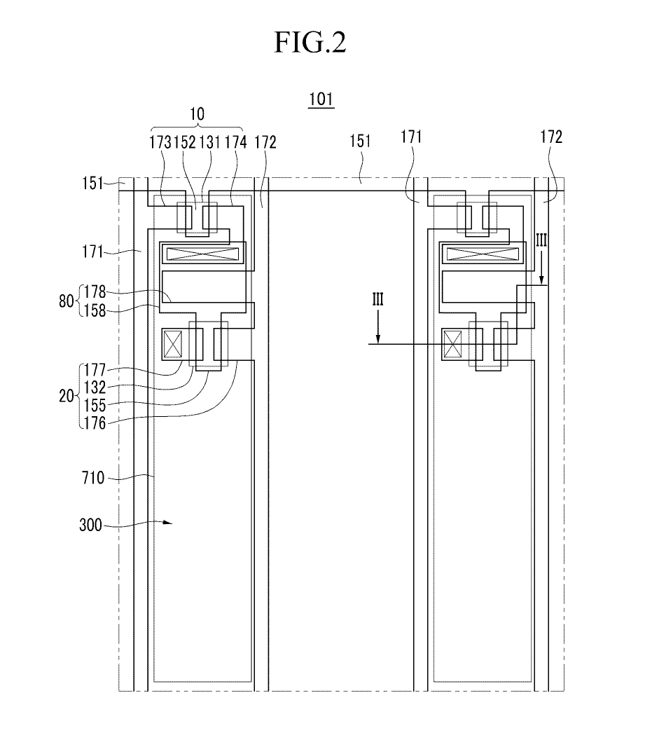

Driving circuitry 200 includes switching and driving thin film transistors 10 and 20 (shown in FIG. 2), and transmits driving signals to the organic light emitting diode 300. The organic light emitting diode 300 emits light in accordance with the received signals from the driving circuitry 200.

The organic light emitting diode 300 is positioned on the driving circuitry 200.

The organic light emitting diode 300 is positioned on a display area on the first substrate 100, and is formed using a microelectromechanical systems (MEMS) technique such as photolithography or the like. The organic light emitting diode 300 receives signals from driving circuitry 200, and displays an image in accordance with the received signals.

The internal structure of the organic light emitting diode 101 will now be described in detail with reference to FIG. 2 thru FIG. 4.

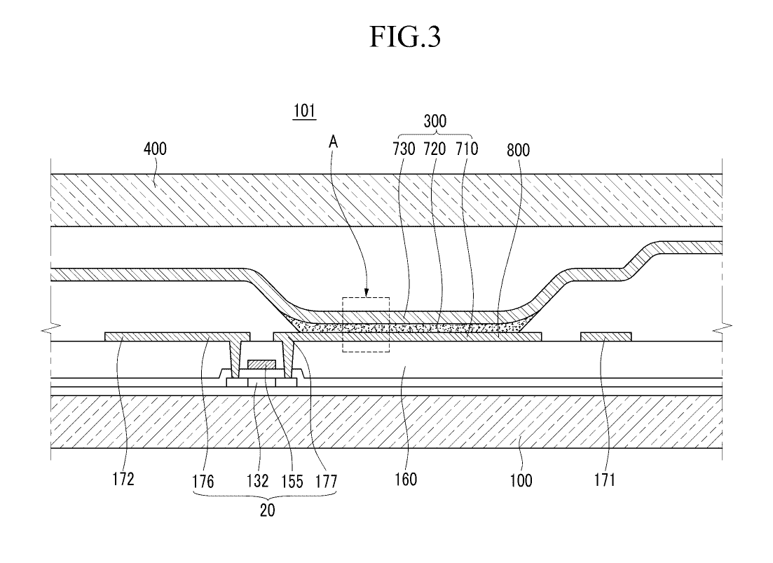

FIG. 2 is a layout view of a pixel structure of an organic light emitting diode display according to an exemplary embodiment. FIG. 3 is a cross-sectional view of the organic light emitting diode display taken along the line of FIG. 2.

One embodiment of the structures of the driving circuitry 200 and the organic light emitting diode 300 are shown in FIGS. 2 and 3. Other structures of driving circuitry 200 and the organic light emitting diode 300 are also possible in other embodiments. For example, although the accompanied drawings illustrate an active matrix (AM) type of organic light emitting diode display having a 2Tr-1Cap structure as a display device, in which one pixel includes two thin film transistors (TFTs) and one capacitor, other embodiments are also possible. The number of thin film transistors, the number of capacitors, and the number of lines of the display device are not limited to the embodiment shown in FIGS. 2 and 3. A pixel refers to the smallest unit displaying an image, and the display device displays an image through a plurality of pixels

As shown in FIG. 2 and FIG. 3, each pixel of an embodiment of the organic light emitting diode display 101 includes a switching thin film transistor 10, a driving thin film transistor 20, a capacitor 80, and an organic light emitting diode 300. The structure with the switching thin film transistor 10, the driving thin film transistor 20, and the capacitor 80 is referred to as driving circuitry 200. The driving circuitry 200 further includes gate lines 151 arranged in a direction of the first substrate 100, a data line 171 insulated from and crossing the gate line 151, and a common power line 172. In one embodiment, a pixel is defined by taking the gate line 151, the data line 171, and the common power line 172.

The switching thin film transistor 10 includes a switching semiconductor layer 131, a switching gate electrode 152, a switching source electrode 173, and a switching drain electrode 174. The driving thin film transistor 20 includes a driving semiconductor layer 132, a driving gate electrode 155, a driving source electrode 176, and a driving drain electrode 177.

The switching thin film transistor 10 may be used as a switch for selecting the pixel to be excited and to thereby emit light. The switching gate electrode 152 is connected to the gate line 151. The switching source electrode 173 is connected to the data line 171. The switching drain electrode 174 is spaced apart from the switching source electrode 173 by a distance, and is connected to a capacitor plate (158 in one embodiment) of the capacitor 80.

The driving thin film transistor 20 applies the driving power to the first electrode 710 to excite an organic emission layer 720 of the organic light emitting diode 300 within the selected pixel. The driving gate electrode 155 is connected to the capacitor plate 158, which is in turn connected to the switching drain electrode 174. The driving source electrode 176 and another capacitor plate (178 in one embodiment) are connected to the common power line 172. The first electrode 710 of the organic light emitting diode 300 extends from the driving drain electrode 177, and the driving drain electrode 177 and the first electrode 710 are connected to each other.

The capacitor 80 includes a pair of capacitor plates 158 and 178, and an interlayer insulating layer 160 is disposed between the capacitor plates 158 and 178. The interlayer insulating layer 160 may function as a dielectric, and the capacitance of the capacitor 80 is determined by the charges stored in the capacitor 80 and the voltage between the capacitor plates 158 and 178.

The switching thin film transistor 10 is driven by a gate voltage applied to the gate line 151 so as to transmit the data voltage applied to the data line 171 to the driving thin film transistor 20. A voltage corresponding to the difference between the common voltage applied to the driving thin film transistor 20 from the common power line 172, and the data voltage transmitted from the switching thin film transistor 10 is stored at the capacitor 80. A current corresponding to the voltage stored at the capacitor 80 flows to the organic light emitting diode 300 through the driving thin film transistor 20 to cause the organic light emitting diode 300 to emit light.

The organic light emitting diode 300 includes a first electrode 710, an organic emission layer 720 placed on the first electrode 710, and a second electrode 730 placed on the organic emission layer 720.

FIG. 4 is a magnified view of the section A of FIG. 3.

In the embodiment of FIG. 4, the first electrode 710 is a transparent electrode, and functions as an anode, and a hole injection electrode. The first electrode 710 may be formed with a single or multiple-layered structure containing at least one transparent or semitransparent conductive material selected from indium tin oxide (ITO), indium zinc oxide (IZO), and silver (Ag). In some embodiments, the first electrode 710 may be formed with a conductive material having a high work function such that it exerts high hole-injection capacity with respect to the organic emission layer 720. The organic emission layer 720 is placed on the first electrode 710.

The organic emission layer 720 includes a main emission layer 721 emitting light, a hole organic layer 722 disposed between the main emission layer 721 and the first electrode 710, and an electron organic layer 723 disposed between the main emission layer 721 and the second electrode 730. The main emission layer 721 is a layer where the injected holes and electrons from the first and second electrodes 710 and 730 are combined with each other. The hole organic layer 722 includes at least one of hole injection layers (HIL) and hole transport layers (HTL), and the electron organic layer 723 includes at least one of electron injection layers (EIL) and electron transport layers (ETL). The main emission layer 721 includes a red emission layer emitting red light, a green emission layer emitting green light, and a blue emission layer emitting blue light. The second electrode 730 is placed on the organic emission layer 720, and functions as a cathode. Holes and electrons from the first and second electrodes 710 and 730 are injected into the organic emission layer 720, and when the excitons being combinations of the injected holes and electrons drop from an excited state to a ground state, the organic emission layer 720 emits light.

The second electrode 730 is a reflective electrode, and functions as a cathode, and an electron injection electrode. In the bottom emission type organic light emitting diode display 101 according to an exemplary embodiment, the organic light emitting diode 300 emits light in the direction of the first substrate 100.

The second electrode 730 includes a first layer 731 placed on the organic emission layer 720, and a second layer 732 disposed between the organic emission layer 720 and the first layer 731.

The first layer 731 is a reflective layer, and the second layer 732 is a semitransparent layer. Specifically, the transmittance of the first layer 731 is in a range from more than about 0% to about 1%, and the transmittance of the second layer 732 is in a range from about 10% to about 100%. The first layer 731 is higher in reflectivity than the second layer 732. The first layer 731 has a first thickness T1, and the second layer 732 has a second thickness T2 that is smaller than the first thickness T1. The first thickness T1 of the first layer 731 may be 1, 2, 3, 4, 5, 6, 7, 8, 9, 10, 15, 20, 25, 30, 35, 40, 45, 50, 55, 60, 65, 70, 75, 80, 85, 90, 95, 100, 150, 200, 250, 300, 350, 400, 450, 500, 550, 600, 650, 700, 750, 800, 850, 900, 950, 1000, 1500, 2000, 2500, 3000, 3500, 4000, 4500, 5000, 5500, or 6000 Å. The first thickness T1 may be in a range formed by any two of the foregoing numbers. For example, the first thickness T1 may be from about 100 Å to about 5000 Å, or about 200 Å to about 5500 Å. In some embodiments, the thickness of the first layer 731 may be about 1000 Å. The second thickness T2 of the second layer 732 is may be 1, 2, 3, 4, 5, 6, 7, 8, 9, 10, 15, 20, 25, 30, 35, 40, 45, 50, 55, 60, 65, 70, 75, 80, 85, 90, 95, 100, 150, 200, 250, 300, 350, 400, 450, 500, 550, 600 Å. The second thickness T2 may be in a range formed by any two of the foregoing numbers. For example, the second thickness T2 may be from about 30 Å to about 500 Å, or about 35 Å to about 550 Å. In some embodiments, the thickness of the second layer 732 may be about 120 Å.

The second layer 732 is thinner than the first layer 731, while the transmittance of the second layer is higher than that of the first layer, such that most of the light components emitted from the organic emission layer 720 and illuminated to the second electrode 730 are reflected by the first layer 731, rather than by the second layer 732, and are illuminated to the outside through the first electrode 710.

Since the reflectivity of the second electrode 730 depends upon the first layer 731, and since the transmittance of the second layer 732 is in a range of about 10% to about 100%, most of the light components emitted from the organic emission layer 720 and illuminated to the first layer 731 are illuminated to the first layer 731 through the second layer 732. Since the transmittance of the first layer 731 is in a range from more than about 0% to about 1%, most of the light components emitted from the organic emission layer 720 and illuminated to the first layer 731 are reflected by the first layer 731, and are illuminated to the outside through the first electrode 710 and the first substrate 100.

In one embodiment, the first layer 731 contains aluminum (Al), but other embodiments are possible. For example, the first layer 731 may contain a highly reflective material such as silver (Ag) and magnesium silver (MgAg).

The second layer 732 is lower in work function than the first layer 731. The work function of the first layer 731 may be in a range from about 3.5 eV to about 6.0 eV. In one embodiment, the work function of the first layer may be about 4.26 eV. The work function of the second layer 732 may be in a range from about 2.0 eV to about 4.5 eV. In one embodiment, the work function of the second layer may be about 3.6 eV. Since the second layer 732 has a low work function, the second electrode 730 exhibits enhanced electron injection capacity with respect to the organic emission layer 720. In some embodiments, the second layer 732 may contain magnesium silver (MgAg), but other embodiments are possible. For example, the second layer 732 may contain a low work function material such as aluminum (Al) and silver (Ag).

With the second electrode 730 functioning as the cathode of the organic light emitting diode display according to an exemplary embodiment, the reflectivity of the second electrode 730 depends upon the reflectivity of the first layer 731, and the electron injection capacity thereof depends upon the electron injection capacity of the second layer 732. As the first layer 731 has high reflectivity and the second layer 732 has a high electron injection capacity, the second electrode 732 is heightened in reflectivity and electron injection capacity such that the organic light emitting diode display exhibits enhanced light emission efficiency.

In an exemplary embodiment, the first electrode 710 functions as an anode while the second electrode 730 as a cathode. In other embodiments, the first electrode may function as a cathode while the second electrode may function as an anode. In such embodiments, the second layer of the second electrode may contains a high work function conductive material so as to increase the second electrode's hole injection capacity.

In one embodiment, the first electrode 710 is a transparent electrode while the second electrode 730 is a reflective electrode. In other embodiments, the first electrode may be a reflective electrode while the second electrode may be a transparent electrode. In such embodiments, the transparent first electrode may include first and second layers while the second layer neighboring the organic emission layer may contain a high work function conductive material so as to increase the first electrode's hole injection capacity.

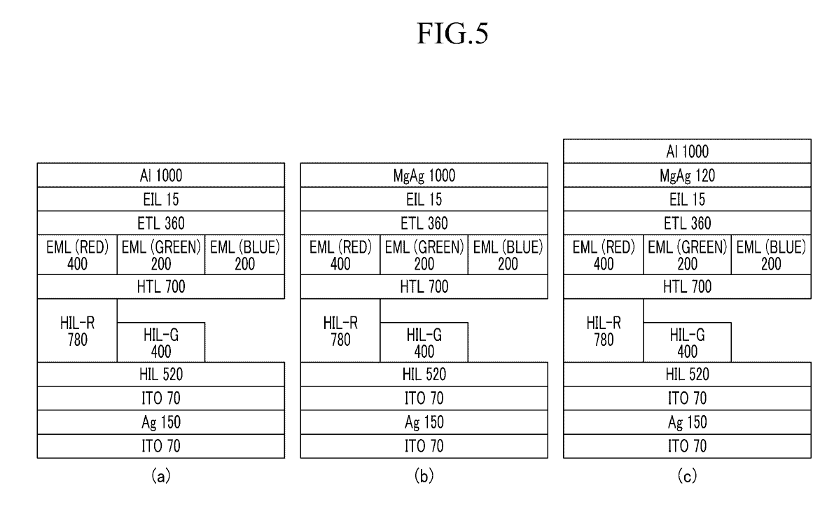

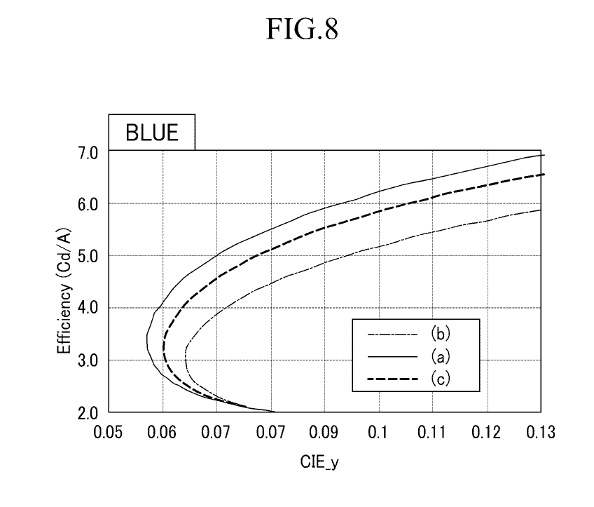

An exemplary embodiment demonstrating reduced reflection of external light will now be described with reference to FIG. 5 thru FIG. 8. The thicknesses of the elements are indicated by the accompanying number, and the unit of thickness is angstroms (Å).

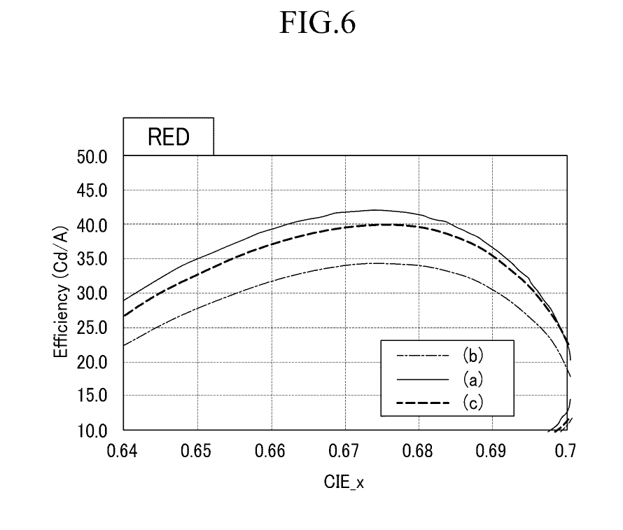

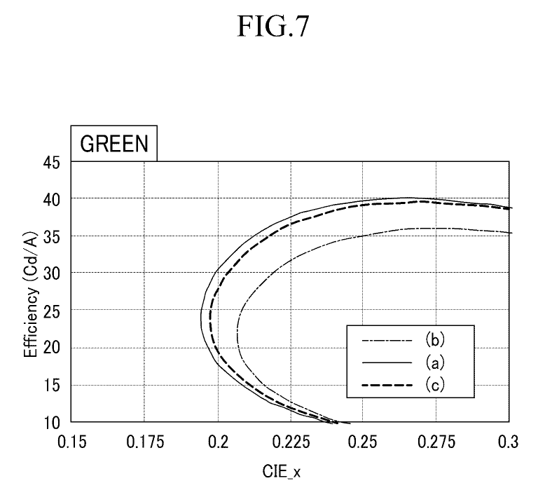

FIG. 5(a), (b), and (c) are schematic sectional views of elements in organic light emitting diode displays according to comparative examples and an exemplary embodiment, respectively. FIG. 6(a), (b), and (c) are graphs representing the CIE color system-based light emission efficiency of the red light measured in the organic light emitting diode displays of FIG. 5. FIG. 7(a), (b), and (c) are graphs representing the CIE color system-based light emission efficiency of the green light measured in the organic light emitting diode displays of FIG. 5. FIG. 8(a), (b), and (c) are graphs representing the CIE color system-based light emission efficiency of the blue light measured in the organic light emitting diode displays of FIG. 5.

FIG. 5(a) is a schematic sectional view of an organic light emitting diode display according to Comparative Example 1. With the organic light emitting diode display according to Comparative Example 1, the first electrode of the organic light emitting diode was formed with an ITO-based first transparent layer ITO 70, a silver-based semitransparent layer Ag 150, and an ITO-based second transparent layer ITO 70. The organic emission layer was formed with a hole injection layer HIL 520, a red subsidiary hole injection layer HIL-R 780, a green subsidiary hole injection layer HIL-G 400, a hole transport layer HTL 700, a red emission layer EML (RED) 400, a green emission layer EML (GREEN) 200, a blue emission layer EML (BLUE) 200, an electron transport layer ETL 360, and an electron injection layer EIL 15. The second electrode was formed with an aluminum-based reflective layer Al 1000.

The CIE color system-based light emission efficiency of the red light of the Comparative Example 1 is represented by the curve (a) of FIG. 6, the efficiency of the green light is represented by the curve (a) of FIG. 7, and the efficiency of the blue light is represented by the curve (a) of FIG. 8.

FIG. 5(b) is a schematic sectional view of an organic light emitting diode display according to Comparative Example 2. With the organic light emitting diode display according to the Comparative Example 2, the first electrode of the organic light emitting diode was formed with an ITO-based first transparent layer ITO 70, a silver-based semitransparent layer Ag 150, and an ITO-based second transparent layer ITO 70. The organic emission layer was formed with a hole injection layer HIL 520, a red subsidiary hole injection layer HIL-R 780, a green subsidiary hole injection layer HIL-G 400, a hole transport layer HTL 700, a red emission layer EML (RED) 400, a green emission layer EML (GREEN) 200, a blue emission layer EML (BLUE) 200, an electron transport layer ETL 360, and an electron injection layer EIL 15. The second electrode was formed with a magnesium silver-based reflective layer MgAg 1000.

The CIE color system-based light emission efficiency of the red light of the Comparative Example 2 is represented by the curve (b) of FIG. 6, the efficiency of the green light is represented by the curve (b) of FIG. 7, and the efficiency of the blue light is represented by the curve (b) of FIG. 8

FIG. 5 (c) is a schematic sectional view of an organic light emitting diode display according to an exemplary embodiment. An organic light emitting diode display according to an exemplary embodiment includes a first electrode formed with an ITO-based first transparent layer ITO 70, a silver-based semitransparent layer Ag 150, and an ITO-based second transparent layer ITO 70. The organic emission layer is formed with a hole injection layer HIL 520, a red subsidiary hole injection layer HIL-R 780, a green subsidiary hole injection layer HIL-G 400, a hole transport layer HTL 700, a red emission layer EML (RED) 400, a green emission layer EML (GREEN) 200, a blue emission layer EML (BLUE) 200, an electron transport layer ETL 360, and an electron injection layer EIL 15. The second electrode is formed with an aluminum-based first layer Al 1000, and a magnesium silver-based second layer MgAg 120.

The CIE color system-based light emission efficiency of the red light of the exemplary embodiment is represented by the curve (c) of FIG. 6, the efficiency of the green light is represented by the curve (c) of FIG. 7, and the efficiency of the blue light is represented by the curve (c) of FIG. 8

It turned out with the organic light emitting diode display shown in FIG. 6(c) according to the Example 1 that the light emission efficiency of the red light was substantially 5% lower than that related to the organic light emitting diode display shown in FIG. 6(a) according to the Comparative Example 1, but substantially 13% higher than that related to the organic light emitting diode display shown in FIG. 6(b) according to the Comparative Example 2.

The light emission efficiency of the green light of the exemplary embodiment was about 5% lower than that of Comparative Example 1, but about 18% higher than that of Comparative Example 2.

The light emission efficiency of the blue light of the exemplary embodiment was about 8% lower than that of the Comparative Example 1, but about 13% higher than that of Comparative Example 2.

In an exemplary embodiment of the organic light emitting diode display, the light emission efficiency is slightly lower than that of an organic light emitting diode display having a second electrode based only on a high reflective metal, but the light emission efficiency is higher than that of an organic light emitting diode display having a second electrode based only on a low work function metal.

In an exemplary embodiment, the second electrode may contain a material that is lower in work function than that of Comparative Example 1, so that the power consumption of the display is reduced, thereby stretching the life span of the organic light emitting diode. Additionally, in an exemplary embodiment, the second electrode may contain a material that is higher in reflectivity than that of Comparative Example 2, so that the light emission efficiency of the display is enhanced. In one embodiment, the first layer of the second electrode may exhibit high reflectivity while the second layer may exhibit high electron injection capacity so that the organic light emitting diode is enhanced in light emission efficiency, and reduced in power consumption. In such embodiments, the overall efficiency of the organic light emitting diode display is enhanced.

While this disclosure has been described in connection with certain exemplary embodiments, it is to be understood that the invention is not limited to the disclosed embodiments, but, on the contrary, is intended to cover various modifications and equivalent arrangements.

What is claimed is:

1. An organic light emitting diode display comprising:
a first electrode;
an organic emissive layer placed over the first electrode and configured to emit light; and
a second electrode comprising a first layer placed over the organic emissive layer and a second layer disposed between the first layer and the organic emissive layer, wherein the first layer has a first transmittance and the second layer has a second transmittance, and wherein the second transmittance is higher than the first transmittance.

2. The organic light emitting diode display of claim 1, wherein the first layer is comprises a reflective layer, and the second layer comprises a semitransparent layer.

3. The organic light emitting diode display of claim 2, wherein the transmittance of the second layer is more than about 10%.

4. The organic light emitting diode display of claim 3, wherein the transmittance of the first layer is less than about 1%.

5. The organic light emitting diode display of claim 2, wherein the second layer is thinner than the first layer.

6. The organic light emitting diode display of claim 5, wherein the first layer is higher in reflectivity than the second layer.

7. The organic light emitting diode display of claim 6, wherein the first electrode functions as an anode, and the second electrode functions as a cathode.

8. The organic light emitting diode display of claim 7, wherein the second layer is lower in work function than the first layer.

9. The organic light emitting diode display of claim 8, wherein the first layer comprises aluminum (Al), and the second layer comprises magnesium silver (MgAg).

10. The organic light emitting diode display of claim 1, wherein the second electrode is configured such that light emitted from the organic emissive layer is partly reflected at the second layer and partly transmitted to the first layer and that the light transmitted to the first layer is mostly reflected back toward the organic emissive layer.

11. An organic light emitting device comprising:
a first electrode;
a second electrode comprising a semi-transmissive layer and a reflective layer; and
an organic emissive layer between the first and second electrodes,
wherein the semi-transmissive layer is positioned between the organic emissive layer and the reflective layer such that light emitted from the organic emissive layer is partially transmitted to the reflective layer and substantially reflected at the reflected layer back toward the organic emissive layer.

12. The device of claim 11, wherein the semi-transmissive layer comprises an electrically conductive material and is in a thickness sufficient to transmit at least 10% of light incident thereto.

13. The device of claim 12, wherein the semi-transmissive layer is substantially thinner than the reflective layer.

14. The device of claim 13, wherein the material of the semi-transmissive layer would be substantially reflective in a thickness of the reflective layer.

15. The device of claim 11, wherein the semi-transmissive layer has a thickness from about 30 Å to about 5000 Å.

16. The device of claim 11, wherein the semi-transmissive layer comprises an electrically conductive material having a work function substantially smaller than that of the reflective layer.

17. The device of claim 11, wherein the reflective layer comprises an electrically conductive material and is in a thickness sufficient to reflect at least 95% of light incident thereto.

18. The device of claim 11, wherein the semi-transmissive layer comprises MgAg.

19. The device of claim 11, wherein the semi-transmissive layer comprises Al.
